(19) United States
(12) Patent Application Publication
(10) Pub. No.: US 2005/0006686 A1
(43) Pub. Date: Jan. 13, 2005

(54) Semiconductor device having trench capacitors and method for making the trench capacitors

(76) Inventors: Shigehiko Saida, Mie (JP); Kiyotaka Miyano, Kanagawa (JP); Takashi Nakao, Kanagawa (JP)

Correspondence Address: Finnegan, Henderson, Farabow,;Garrett & Dunner, L.L.P., 1300 I Street, N.W., Washington, DC, 20005-3315, US

(21) Appl. No.: 10/770,470

(22) Filed: Feb. 4, 2004

(30) Foreign Application Priority Data
Feb. 7, 2003 (JP) P2003-030795

(51) Int. Cl. H01L 29/76

(52) U.S. Cl. 257/301

(57) ABSTRACT

A semiconductor device having a trench capacitor is disclosed. The trench is formed on the surface of a semiconductor substrate. A first insulating film is formed on the side wall of the trench and a semiconductor film is buried in the trench. The first insulating film and the semiconductor film located in the upper part of the trench are etched and a second insulating film is deposited on the exposed side wall. The semiconductor film and the first insulating film are etched and a plate electrode is formed on the exposed side wall. A capacitor insulating film is formed on the plate electrode and a storage electrode is buried within the trench. The structure provides a semiconductor device having fewer memory cell defects.

### CROSS REFERENCE TO RELATED APPLICATIONS

This application is based upon and claims the benefit of priority from prior Japanese Patent Applications No. P2003-030795, filed on Feb. 7, 2003; the entire contents of which are incorporated herein by reference.

### BACKGROUND OF THE INVENTION

1. Field of the Invention

The invention relates to a semiconductor device having trench capacitors and a method for making the trench capacitors.

2. Description of the Related Art

Recently, semiconductor devices have been developed as a memory device for an information processing device. Since the semiconductor device does not have mechanically driven components, the semiconductor device has high mechanical impact immunity and high-speed accessibility. Such semiconductor devices include memory cells. The memory cells have been made smaller by recent developments of semiconductor technology, especially, by the design rule shrinkage. The shrinkage of the memory cells has been required so as to provide highly integrated, higher density semiconductor devices. By use of the fine feature size processing of the cells, problems have been caused associated with memory storing characteristics of the memory cells.

In a dynamic random-access memory (DRAM) of the semiconductor device, the memory cells include a MOS (metal oxide semiconductor) transistor, and a storage capacitor which is connected in series to the MOS transistor. In a DRAM, the shrinkage of the memory cells has a tendency to reduce the area and a decreased capacitance of the capacitor. There has been a possibility that the decreased capacitance generates problems in which data stored in the memory cells is misread and a software error may occur which is caused when the data stored in the memory cells is damaged by alpha rays.

In order to solve the above problems, it is important not to reduce the capacitance of the capacitor even under shrinkage of the memory cells. In order not to reduce the storage capacitance of the capacitor, a trench in which a capacitor is formed has been etched deeper to increase the area of the capacitor. However, it has become difficult in the present manufacturing technology to etch the trench deeper. Moreover, the thickness of the insulating film of the capacitor has been made thinner so as to keep the required storage capacitance. However, it has also become difficult in the present manufacturing technology to make the thickness of the insulating film thinner.

Then, two approaches have been proposed by which the storage capacitance is not reduced: a first approach by which a trench is formed as a bottle-type trench; and a second approach by which a plate electrode is formed through doping under vapor-phase diffusion. However, there have been cases in which other storage characteristics of the memory cells are deteriorated by use of the above methods.

### SUMMARY OF THE INVENTION

An aspect of the present invention inheres in a semiconductor device according to embodiments of the present invention. The semiconductor device includes a semiconductor substrate having a first conductivity type and including an side wall and a bottom face enclosed by the side wall, a plate electrode having a second conductivity type different from the first conductivity type, wherein the plate electrode is provided from the bottom face to the side wall in the semiconductor substrate, a capacitor insulating film provided on the bottom face and the side wall, a collar oxide film provided on the side wall, a ring-shaped lower end of the collar oxide film being in contact with the capacitor insulating film and the collar oxide film is in contact with the plate electrode, a storage electrode provided on the plate electrode and the capacitor insulating film, a height of an upper surface of the storage electrode is higher than a height of an upper end of the collar oxide film, a capacitor extraction electrode provided on the upper end of the collar oxide film and on the upper surface of the storage electrode, the capacitor extraction electrode being electrically connected to the storage electrode and in contact with an upper part of the side wall, and a buried strap region provided within the semiconductor substrate including the upper part of the side wall, the buried strap region being in contact with the collar oxide film and electrically connected to the capacitor extraction electrode, the buried strap region having the second conductivity type.

Another aspect of the present invention inheres in a method of making a trench capacitor according to embodiments of the present invention. The method of making a trench capacitor includes forming a trench on a surface of a semiconductor substrate having a first conductivity type, forming a first insulating film on an side wall of the trench, depositing a semiconductor film in the trench on the first insulating film, etching the first insulating film and the semiconductor film located in an upper part of the trench, depositing a second insulating film on an exposed side wall of the trench, etching the semiconductor film, etching the first insulating film, forming a plate electrode of a second conductivity type different from the first conductivity type on the exposed side wall of the trench by a vapor-phase diffusion method, forming a capacitor insulating film on the plate electrode, and burying a storage electrode in the capacitor insulating film and in the second insulating film within the trench.

### BRIEF DESCRIPTION OF DRAWINGS

FIG. 1 is a cross section of a semiconductor device according to a first embodiment;

FIGS. 2A-2T are cross sections for explaining steps to execute a method of manufacturing the semiconductor device according to the first embodiment;

FIG. 3 is a graph representing a relation between an etching rate of silicon germanium and a mole fraction of germanium;

FIG. 4 is a graph representing a relation between a capacitance of a trench capacitor and a voltage of a storage electrode in the semiconductor device according to the first embodiment;

FIG. 5 is a cross section of a semiconductor device according to a second embodiment; and

FIGS. 6A-6C are cross sections for explaining steps to execute a method of manufacturing the semiconductor device according to the second embodiment.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### Deterioration in Data Retention Characteristics of Memory Cells

Two approaches have been made by which the capacitance is not reduced. However, it has been shown that, in some cases, the memory cell capacitance is reduced and other retention characteristics are deteriorated when the above approaches are used.

It is now clear that deterioration in the memory storing characteristics is generated by a defect in a buried strap region which is electrically connected to a storage electrode of the capacitor and a drain region of a transistor at the junction between the buried strap region and the semiconductor substrate. Because of this defect, a junction leakage current is increased by the defect generated in the buried strap region.

The capacitor includes a collar oxide film which separates the plate electrode and the storage electrode. It has been determined that a reason for generation of the defect in the buried strap region is that a normal stress on the collar oxide film with respect to the side wall of the trench is a compressive stress.

A collar insulating film is grown by a thermal oxidation method of a Local Oxidation of Silicon (LOCOS) collar. As above collar oxide film is formed before formation of the capacitor, the above two methods can be utilized, that is, the method by which the trench is formed as a bottle-type trench; and the method by which the plate electrode is formed by doping under vapor-phase diffusion.

When the collar oxide film is grown by the thermal oxidation method, the side wall of the trench is oxidized. The volume of the collar oxide film grown by oxidation is larger than the volume of the semiconductor substrate employed in the oxidation. Moreover, the volume of the collar oxide film which can grow in the trench is smaller than that of the thermally-oxidized film which can grow on a flat surface of the semiconductor substrate. Thereby, a compressive stress is produced within the collar oxide film. It has been determined that compressive stress from the collar oxide film to the buried strap region is created. A defect is generated in the buried strap region by the above stress.

Then, it has been determined that the stress from the collar oxide film to the buried strap region should be prevented in order to prevent generation of the defect. That is, the compressive stress should not be generated within the collar oxide film.

(First Embodiment)

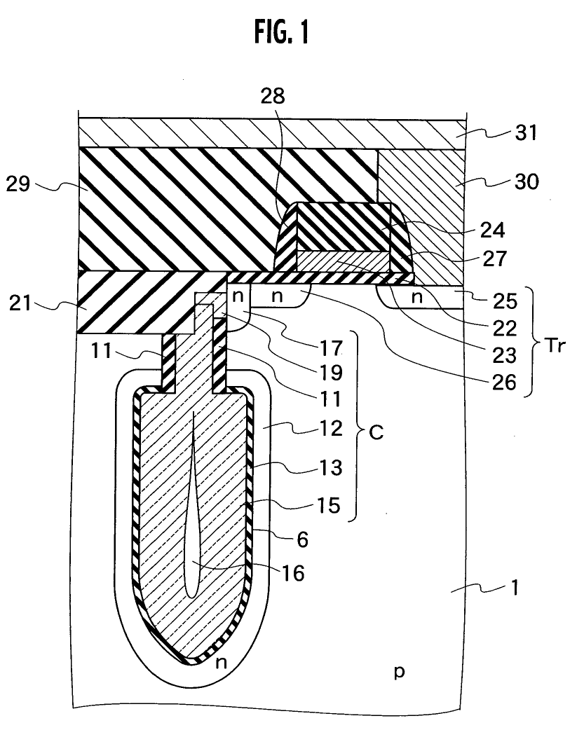

A semiconductor device according to a first embodiment of the present invention encompasses a plurality of memory cells. Each of the memory cell embraces the capacitor and the MOS transistor as shown in FIG. 1. Each of memory cells is insulated from each other by an isolation region 21 therebetween.

The storage capacitor is arranged in a trench of a p-type silicon (Si) substrate 1. The storage capacitor includes a plate electrode 12, a capacitor insulating film 13, a collar oxide film 11, a storage electrode 15, a capacitor extraction electrode 19, and a buried strap region 17.

The plate electrode 12 including the bottom face and the side wall of the trench is provided within the silicon substrate 1. The plate electrode 12 has an n type conductivity. The capacitor insulating film 13 is provided from the bottom face to the upper part of the side wall. The capacitor insulating film 13 is provided on the plate electrode 12.

The collar oxide film 11 is provided above the side wall of the trench, i.e., at the top of the trench. The ring-shaped lower end of the collar oxide film 11 is in contact with the capacitor insulating film 13. The collar oxide film 11 is also in contact with the plate electrode 12. A normal stress on the collar oxide film 11 with regard to the side wall of the trench is a tensile stress. The collar oxide film 11 is deposited on the side wall of the trench, preferably, by a chemical vapor deposition (CVD) method.

The storage electrode 15 is provided on the capacitor insulating film 13. The height of the upper surface of the storage electrode 15 is higher than that of the upper end of the collar oxide film 11. The interface between the storage electrode 15 and the extraction electrode 19 does not coincide with a plane on which the lower end of the collar oxide film 11 is an outer edge. In the storage electrode 15, the width at the side wall in contact with the capacitor insulating film 13 is larger than that at the side wall in contact with the collar oxide film 11.

The capacitor extraction electrode 19 is provided on the upper end of the collar oxide film 11 and on the upper surface of the storage electrode 15. The capacitor extraction electrode 19 is electrically connected to the storage electrode 15. The capacitor extraction electrode 19 is in contact with the upper surface of the side wall of the trench. The buried strap region 17 is provided within the silicon substrate 1 including the upper surface of the side wall of the trench. The buried strap region 17 is in contact with the collar oxide film 11 and is electrically connected to the capacitor extraction electrode 19. The buried strap region 17 has an n type conductivity.

The MOS transistor is arranged in the neighborhood of the trench in the silicon substrate 1. The MOS transistor encompasses a drain region 26, a gate insulating film 22, a gate electrode 23, and a source region 25.

The drain region 26 is provided within the silicon substrate 1 including the upper surface of the substrate 1. The drain region 26 is electrically connected to the buried strap region 17. The drain region 26 has an n type conductivity. The gate insulating film 22 is provided on the upper surface of the silicon substrate 1. The gate electrode 23 is provided on the gate insulating film 22 and above the drain region 26. The source region 25 is provided under the gate insulating film 22, below the gate electrode 23, and separate from the drain region 26 within the silicon substrate 1 including the upper surface of the substrate 1. The source region 25 has an n type conductivity.

In addition the semiconductor device includes a contact plug 30 provided on the source region 25 and a bit line 31 which is electrically connected to the source region 25. The bit line 31 is provided on an interlevel insulator 29. The gate electrode 23 and the contact plug 30 are insulated from each other with a silicon nitride film 24 and side walls 27, 28. The isolation region 21 is provided on the capacitor extraction electrode 19.

With regard to the semiconductor device according to the first embodiment, substantially no defects are generated in the buried strap region 17, because the normal stress on the collar oxide film 11 with respect to the side wall of the trench is not compressive stress. While it is possible that no stress of any type is induced, there may be cases where only a small amount of tensile stress is induced. Here, it is obvious that, even if normal stress is compresive stress, the stress may be small so that no defect is generated. In order to reduce the intensity of the normal stress and to further make the stress a tensile stress, the collar oxide film 11 is just required to be provided on the side wall of the trench, not by the thermal oxidation method, but by chemical vapor deposition, as described above.

Moreover, with regard to the storage electrode 15, no interface exists with a plane on which the lower end of the collar oxide film 11 is an outer edge. Thereby, it is apparent that the storage electrode 15 is formed at a time with regions in contact with the capacitor insulating film 13 and the collar oxide film 11. A natural oxidation film is not formed on the surface of the region in contact with the capacitor insulating film 13, and a natural oxidation film is not formed on the interface between the region in contact with the capacitor insulating film 13 and the region in contact with the collar oxide film 11. Thereby, a parasitic resistance of the storage capacitor can be reduced. Further, the writing and reading speeds of data can be increased in the memory cells.

As explained above, the semiconductor device in which in the data retention characteristics is not deteriorated, even under shrinkage of the memory cells, can be provided.

A method of manufacturing the semiconductor device according to the first embodiment of the present invention will be explained. The method of manufacturing the semiconductor device includes a method of forming a trench capacitor. In the first place, the method of forming the trench capacitor is executed.

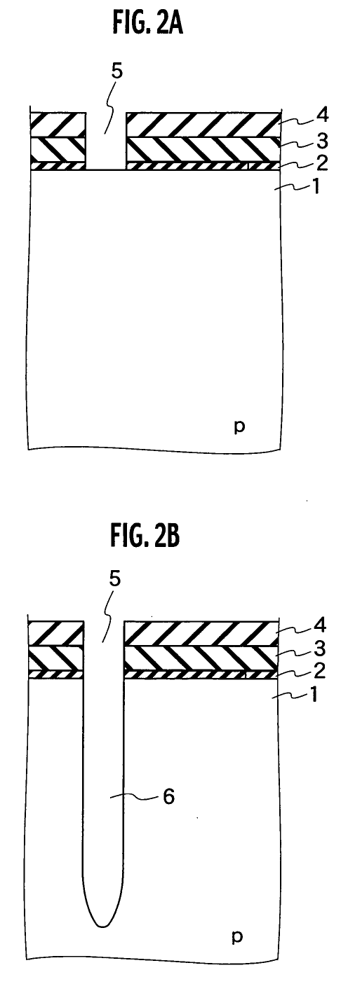

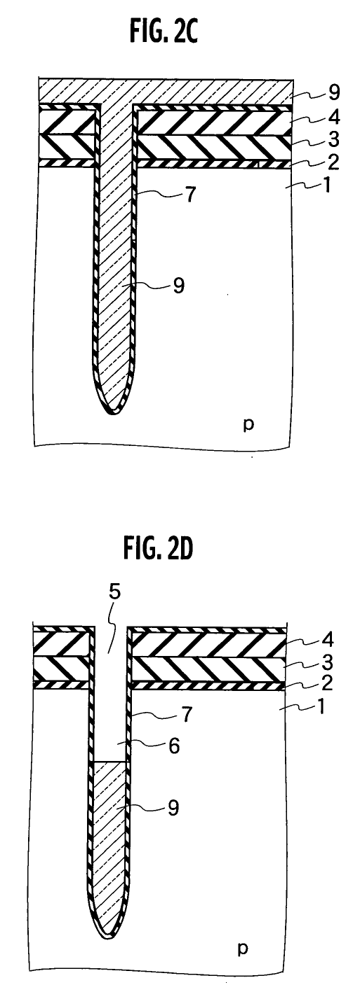

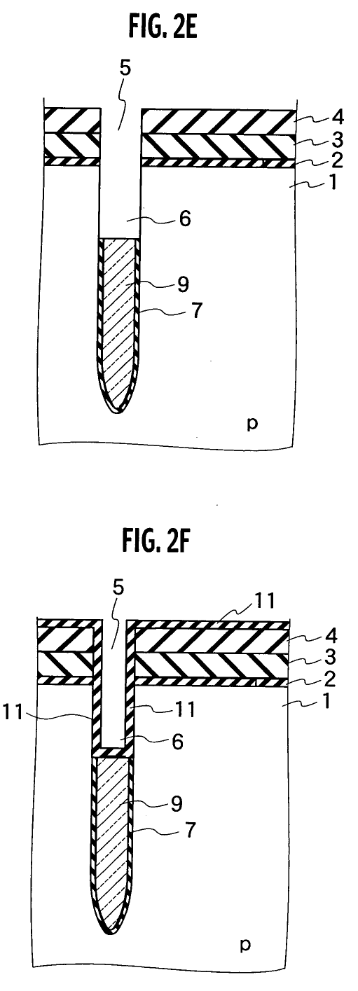

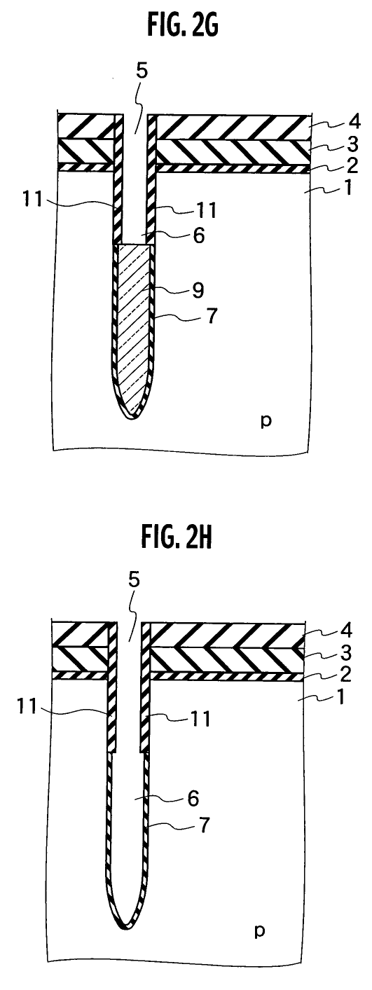

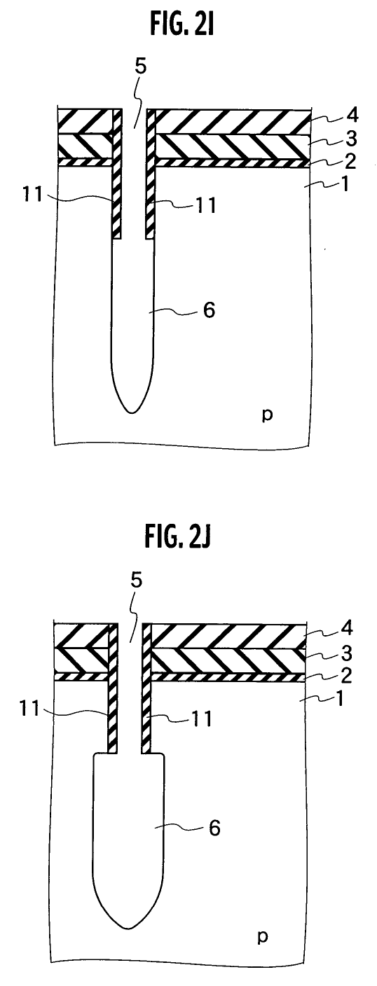

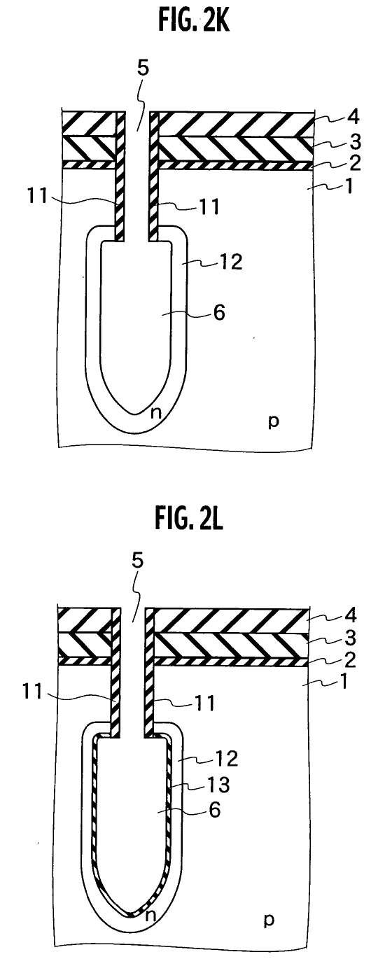

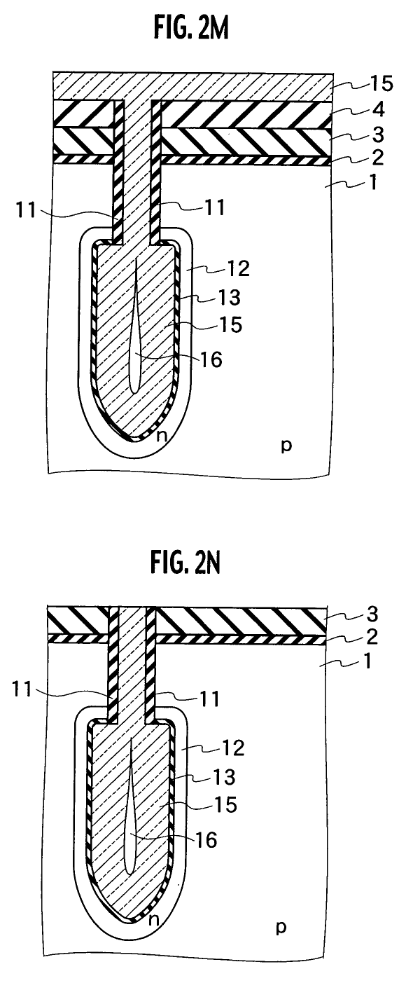

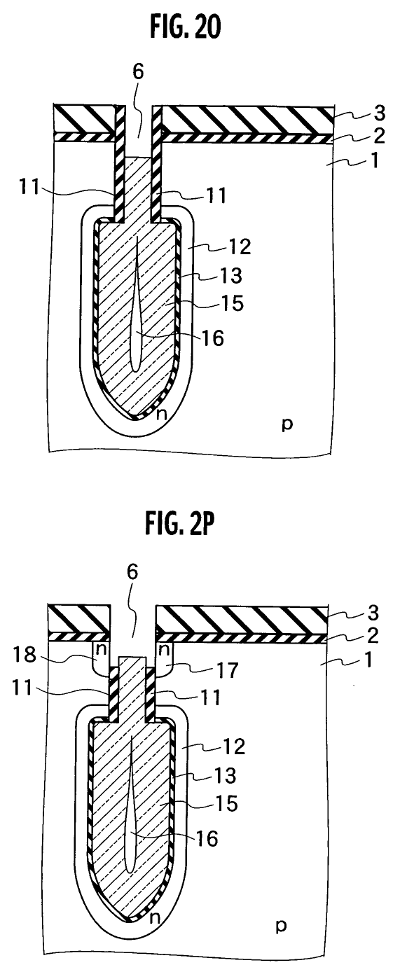

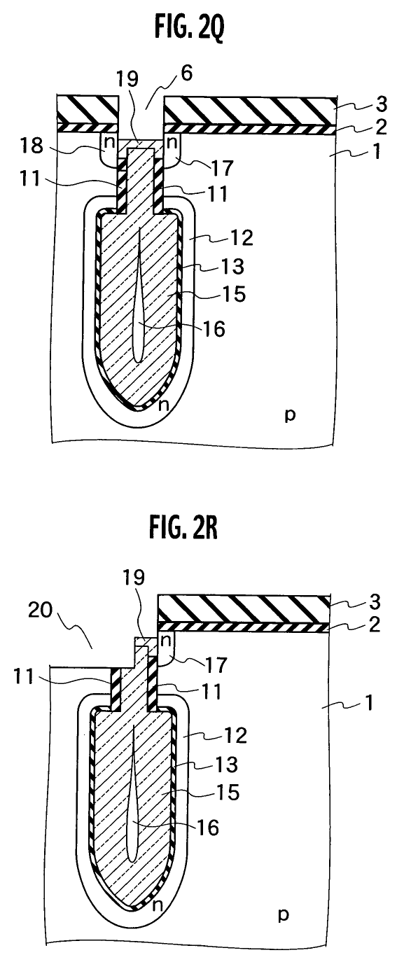

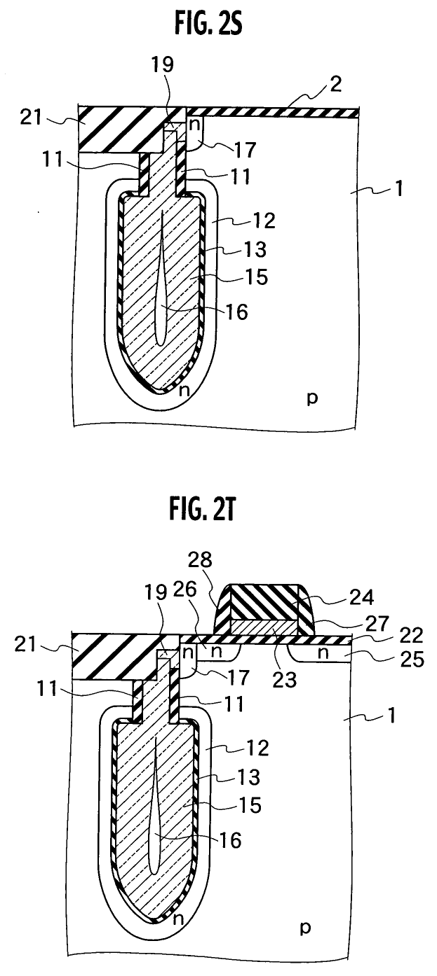

(a) A thermally-oxidized film 2 is grown on the p-type silicon substrate 1. A silicon nitride film 3 and a silicon oxide film 4 are deposited on the thermally-oxidized film 2 by the CVD method. As shown in FIG. 2A, using a photolithographic technique, a trench 5 is formed at a position at which a trench capacitor is formed.

(b) As shown in FIG. 2B, anisotropic etching of the silicon substrate 1 to form a trench 6 is executed, using the thermally-oxidized film 2, the silicon nitride film 3 and the silicon oxide film 4 as a mask.

(c) A silicon nitride film 7 is deposited on the side walls of the trenches 5, 6, and on the silicon oxide film 4 by the CVD method. The film thickness of the silicon nitride film 7 was set at 5 nm. As shown in FIG. 2C, a part of a silicon germanium (SiGe) film 9 is buried in the trenches 5; 6 as a dummy buried layer for deposition of the collar oxide film by the CVD method. Another part of the silicon germanium film 9 is formed on the silicon nitride film 7 above the silicon oxide film 4. When the silicon germanium film 9 was deposited, mono silane (SiH₄) and mono germane (GeH₄) were used as a source gas. The flow rates of mono silane and mono germane at the formation were 250 sccm and 500 sccm, respectively. The deposition pressure in a reactor was 133 Pa. The deposition temperature for the silicon substrate 1 was 450 degrees Celsius at the formation.

(d) As shown in FIG. 2D, the upper part of the silicon germanium film 9 is etched by a chemical dry etching (CDE) method and the silicon germanium film 9 is left only in the lower part of the trench 6. As shown in FIG. 2E, the exposed silicon nitride film 7 is etched and removed.

(e) As shown in FIG. 2F, a silicon oxide film 11 for a collar oxide film is deposited on the exposed side walls of the trenches 5, 6 by the CVD method. Moreover, the silicon oxide film 11 was also deposited on the silicon oxide film 4. The silicon oxide film 11 was a TEOS oxide film and the film thickness of the film 11 was set at 20 nm. A low pressure CVD (LPCVD) method may be used in order to set a normal stress on the collar oxide film 11 with regard to the side wall of the trench 6 to be a tensile stress. The stress produced by the LPCVD method is less than that created by the oxidation method. Moreover, control of the stress can be achieved by changing the deposition temperature.

(f) As shown in FIG. 2G, the collar oxide film 11 deposited on the bottom face of the trench 6 and on the silicon oxide film 4 are etched by anisotropic etching under reactive ion etching (RIE), and are removed. The collar oxide film 11 remains only at the side walls of the trenches 5, 6. The silicon germanium film 9 is exposed.

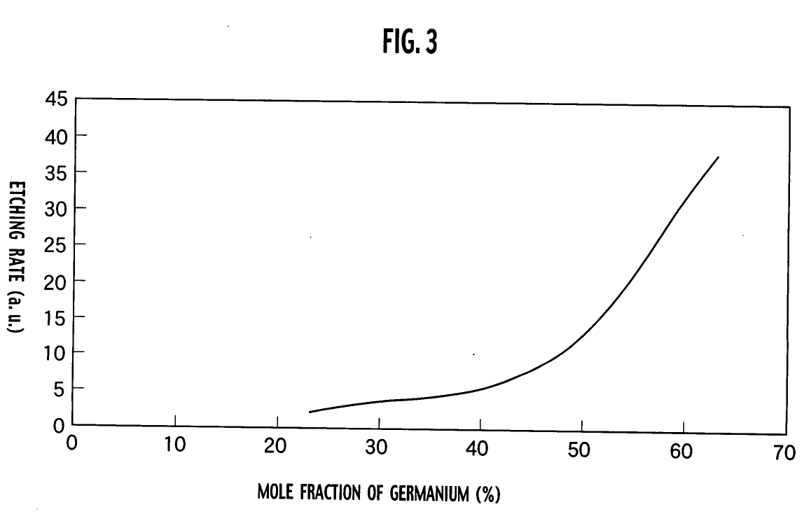

(g) As shown in FIG. 2H, the silicon germanium film 9 remaining in the lower part of the trench 6 is etched with an etchant including a hydrogen peroxide solution (H₂O₂). As shown in FIG. 3, a larger mole fraction of germanium (Ge) in silicon germanium can cause the etching rate to increase. On the other hand, it seems that the silicon substrate 1, the silicon oxide film 4, the silicon oxide film 11, and the silicon nitride film 7 are substantially unetched by an etchant including a hydrogen peroxide solution. Thereby, the silicon germanium film 9 can be removed by using an etchant including the hydrogen peroxide solution without etching the silicon substrate 1, the silicon oxide film 4, the silicon oxide film 11, and the silicon nitride film 7. Here, as shown in FIG. 3 the slope of the etching rate at a mole fraction of germanium of less than 50% is smaller than that in the case where the mole fraction is equal to or larger than 50%. Thereby, the etching rate of silicon germanium can be easily increased by providing the mole fraction of germanium to be equal to or larger than 50%. As shown in FIG. 21, the silicon nitride film 7 is removed by etching.

(h) As shown in FIG. 2J, the side wall of the trench 6 is etched with diluted hydrogen fluoride nitric acid mixture (HF-HNO₃), using the collar oxide film 11 as a mask. As shown in FIG. 2K, an n-type diffusion layer which becomes the plate electrode 12 is formed on the exposed side wall of the trench 5 by vapor-phase diffusion. As shown in FIG. 2L, the capacitor insulating film 13 is formed on the plate electrode 12. An oxynitride silicon film was formed as the capacitor insulating film 13.

(i) As shown in FIG. 2M, n-type polysilicon columns are buried in the trenches 5, 6 on the capacitor insulating film 13 and the collar oxide film 11 as the storage electrode 15. An n-type silicon film 14 is formed on the silicon oxide film 4. A void 16 is generated in the storage electrode 15. Thereby, formation of the trench capacitor having the plate electrode 12 and the storage electrode 15 as terminals is completed.

(j) The substrate is etched back to the height of the upper surface of the silicon nitride film 3 as shown in FIG. 2N. As shown in FIG. 2O, the upper part of the storage electrode 15 is etched so that the height of the upper surface of the storage electrode 15 is lower than that of the surface of the silicon substrate 1. As shown in FIG. 2P, the upper end of the collar oxide film 11 is etched so that the height of the upper end of the collar oxide film 11 is lower than that of the upper surface of the storage electrode 15. The silicon substrate 1 is exposed to the side wall of the trench 6. N-type diffusion layers which become the buried strap regions 17, 18 are formed on the silicon substrate 1 exposed by the vapor-phase diffuision method. As shown in FIG. 2Q, the capacitor extraction electrode 19 in contact with the storage electrode 15 and the buried strap region 17 is buried in the trench 6 by depositing and etching back an n-type polysilicon film. Thereby, formation of a trench capacitor having the capacitor extraction electrode 19 and the plate electrode 12 as terminals is completed. The entire trench capacitor which has been formed is arranged at a lower position than that of the surface of the silicon substrate 1.

(k) In addition, a trench 20 is formed on the silicon substrate 1, as shown in FIG. 2R. A silicon insulating film is deposited on the substrate 1 and the isolation region 21 is formed on the substrate 1 after etching back, as shown in FIG. 2S. The silicon oxide film 2 is etched to form a silicon oxide film, which becomes the gate insulating film 22, on the exposed silicon substrate 1. An n-type polysilicon film 23 and a silicon nitride film 24 are deposited on the substrate 1 to etch the films 23, 24 into a pattern of the gate electrode 23. Ion implantation is conducted, using the silicon nitride film 24 as a mask, to form the drain region 26 and the source region 25. Thereby, formation of the MOS transistor is completed.

(1) As shown in FIG. 2T, a silicon nitride film which becomes the side walls 27, 28 is formed on the side walls of the n type polysilicon film 23 and the silicon nitride film 24. The layer insulating film 29 is formed on the MOS transistor and the isolation region 21. A contact hole is opened on the source region 25. A contact plug 30 is buried in the contact hole. As shown in FIG. 1, a bit line 31 is formed on the layer insulating film 29 and the contact plug 30. Thereby, formation of a semiconductor device having the trench capacitor is completed. The method of forming the trench capacitor is provided in which deterioration in the memory storing characteristics is prevented even under finer-line processing of the memory cells.

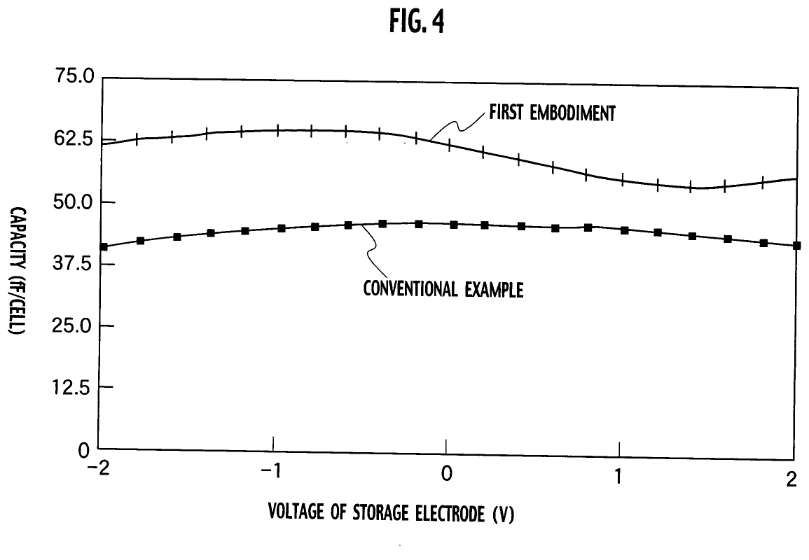

The vapor-phase diffusion method can be applied to impurity diffusion in the side wall of the trench 6 for forming the plate electrode 12, using the method of manufacturing the semiconductor device according to the first embodiment. Thereby, a diffusion layer with higher concentration of impurities can be formed, in comparison with that of a solid-phase diffuision method using conventional arsenic silicate glass (AsSG). An effective film thickness of the capacitor insulating film 13 can be reduced. The capacity of the trench capacitor can be increased by a factor of 1.5, as shown in FIG. 4. Moreover, the manufacturing time of the semiconductor device can be decreased because the solid-phase diffusion method, requiring a longer processing time, can be omitted.

Moreover, in conventional methods, burial and etching have been required to be repeated twice in order to form the storage electrode 15 in the trench 6. Thereby, an interface of the natural oxidation film has been created which divides the storage electrode 15 into two sections. In the method of manufacturing the semiconductor device according to the first embodiment, burial and etching are executed only once in order to form the storage electrode 15. Accordingly, there is no interface of the natural oxidation film which divides the storage electrode 15. Electrical resistance of the storage electrode 15 can be decreased in the first embodiment in comparison with that of a conventional example.

(Variant of the First Embodiment)

In the first embodiment, silicon germanium has been buried in the trench 6 to remove the silicon germanium with the hydrogen peroxide solution after forming the collar oxide film 11. The invention is not limited to the above embodiment. Instead of the silicon germanium, amorphous silicon (Si) may be used. A mixed solution of hydrofluoric acid-nitric acid-acetic acid can be used as an etchant of the amorphous silicon. Moreover, the amorphous silicon may be etched with a chlorinated gas such as chlorine trifluoride (ClF₃), and hydrochloric acid (HCl).

In the first embodiment, the semiconductor film such as a silicon germanium film and amorphous silicon film is formed and the collar oxide film 11 is formed, using the semiconductor film as a dummy storage electrode. Then, the semiconductor film is removed, using the collar oxide film 11 as a mask. The semiconductor film is used because selective etching of the silicon oxide film and the silicon nitride film can be executed and the semiconductor film stably exists at the deposition temperatures of the silicon oxide film and the silicon nitride film. Here, it is further beneficial that an etchant exists, similar to the case of the silicon germanium, so that selective etching of the semiconductor film and the silicon substrate 1 can be conducted.

The semiconductor device including the memory cells may be DRAM, or a system LSI in which DRAM is installed as a mega cell.

(Second Embodiment)

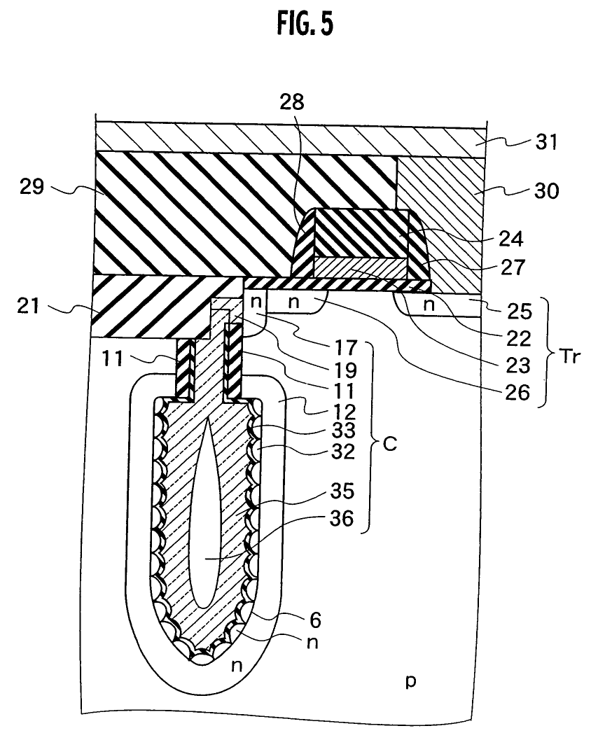

A semiconductor device according to the second embodiment of the present invention has a structurally different capacitor from that of the semiconductor device according to the first embodiment of FIG. 1, as shown in FIG. 5. The semiconductor device according to the second embodiment has irregularities on the bottom face and the side of a trench of a silicon substrate 1. An irregular silicon film 32 is provided on the surface of a plate electrode 12. A hemispherical grained (HSG) polysilicon film, a rough polysilicon film and the like were used for the irregular silicon film 32. A capacitor insulating film 33 is provided on the irregular silicon film 32. The film thickness of the capacitor insulating film is sufficiently thinner in comparison with the difference between the highest and lowest points on the irregular silicon film 32. A storage electrode 35 is provided on the surface of the capacitor insulating film 33.

Thereby, the surface area on which the capacitor insulating film 33 is in contact with the irregular silicon film 32 can be increased compared to a case in which the silicon film 32 is not irregular. Moreover, the surface area on which the capacitor insulating film 33 is in contact with the storage electrode 35 can be increased compared to a case in which the silicon film 32 is not irregular. The capacity of a trench capacitor can be further increased compared to that of the trench capacitor C of the semiconductor device according to the first embodiment.

A method of manufacturing the semiconductor device according to the second embodiment of the invention will be explained. The method of manufacturing the semiconductor device according to the second embodiment includes the method of forming the trench capacitor C. The method of manufacturing the semiconductor device according to the second embodiment and that according to the first embodiment are different from each other in the method of forming the trench capacitor C. Consequently, the method of forming the trench capacitor C will be explained.

(a) In the first place, the method of forming the trench capacitor C according to the first embodiment is executed until the step of FIG. 21.

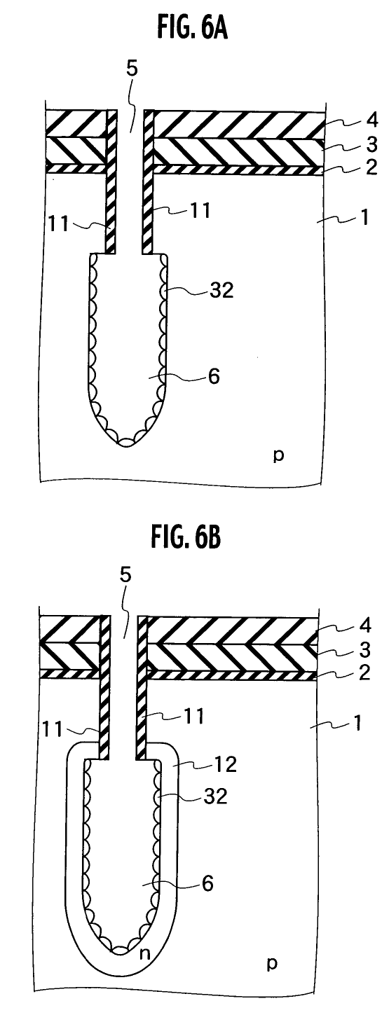

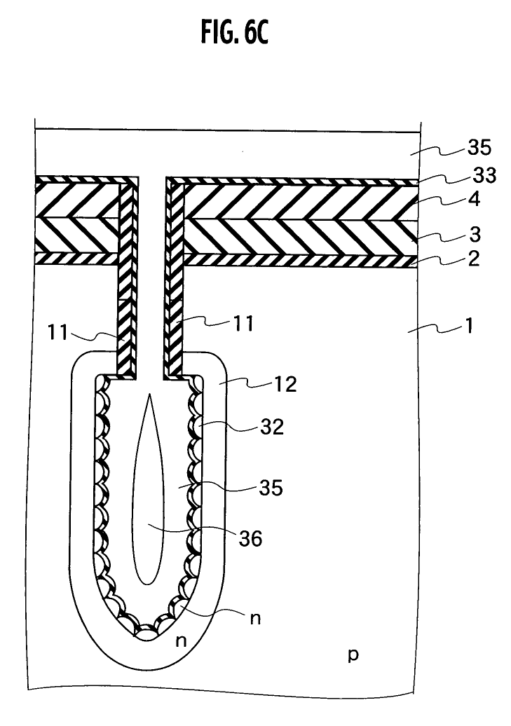

(b) Then, the irregular silicon film 32 is formed on the surface of the exposed silicon substrate 1 within a trench 6 as shown in FIG. 6A. The HSG polysilicon film or the rough polysilicon film is deposited on the surface of the exposed silicon substrate 1 by a selective CVD method.

(c) As shown in FIG. 6B, a dopant is diffused into the irregular silicon film 32 and the silicon substrate 1 by the vapor-phase diffusion method, using a collar oxide film 11 as a mask. An n-type diffusion layer is formed on the irregular silicon film 32. An n-type diffusion layer which becomes the plate electrode 12 is formed on the silicon substrate 1. The capacitor insulating film 33 is formed on the irregular silicon film 32, the collar oxide film 11, and a silicon oxide film 4. A silicon nitride film is formed by the CVD method and is oxidized to form a silicon oxide/silicon nitride stacked film as a capacitor insulating film 13. (d) An n-type polysilicon column is buried as the storage electrode 35 in the trenches 5, 6 on the capacitor insulating film 33, as shown in FIG. 6C. An n-type silicon film 34 is formed on the capacitor insulating film 33 above the silicon oxide film 4. A void 36 is generated in the storage electrode 35. Thereby, formation of the trench capacitor having the plate electrode 12 and the storage electrode 35 as terminals is completed.

Subsequent steps for the method of manufacturing the semiconductor device according to the second embodiment are executed from the step of FIG. 2N for the method of manufacturing the semiconductor device according to the first embodiment. Thereby, formation of the trench capacitor having a capacitor extraction electrode 19 and the plate electrode 12 as terminals is completed, and formation of the semiconductor device having a MOS transistor and the trench capacitor as shown in FIG. 5 is completed.

The invention is not limited to the above first and second embodiments. Though the above explanations applied to the use of the silicon substrate 1, the silicon substrate 1 is only required to be a semiconductor substrate. The semiconductor substrate may be a silicon layer of a silicon on insulator (SOI) substrate, or, silicon germanium (SiGe) mixed crystal, silicon germanium carbide (SiGeC) mixed crystal and the like. The invention can be carried out by various modifications without departing from the points of the present invention

The present invention may be embodied in other specific forms without departing from the spirit or essential characteristics thereof. The embodiments are therefore to be considered in all respects as illustrative and not restrictive, the scope of the present invention being indicated by the appended claims rather than by the forgoing description, and all changes which come within the meaning and range of equivalency of the claims are therefore intended to be embraced therein.

1. A semiconductor device comprising:
a semiconductor substrate having a first conductivity type and including an side wall and a bottom face enclosed by the side wall;
a plate electrode having a second conductivity type different from the first conductivity type, wherein the plate electrode is provided from the bottom face to the side wall in the semiconductor substrate;
a capacitor insulating film provided on the bottom face and the side wall;
a collar oxide film provided on the side wall, a ring-shaped lower end of the collar oxide film being in contact with the capacitor insulating film and the collar oxide film is in contact with the plate electrode;
a storage electrode provided on the plate electrode and the capacitor insulating film, a height of an upper surface of the storage electrode is higher than a height of an upper end of the collar oxide film;
a capacitor extraction electrode provided on the upper end of the collar oxide film and on the upper surface of the storage electrode, the capacitor extraction electrode being electrically connected to the storage electrode and in contact with an upper part of the side wall; and
a buried strap region provided within the semiconductor substrate including the upper part of the side wall, the buried strap region being in contact with the collar oxide film and electrically connected to the capacitor extraction electrode, the buried strap region having the second conductivity type.

2. The semiconductor device as claimed in claim 1, wherein a normal stress on the collar oxide film with respect to the side wall is a tensile stress.

3. The semiconductor device as claimed in claim 1, wherein the collar oxide film is provided on the side wall by deposition.

4. The semiconductor device as claimed in claim 1, wherein the collar oxide film is provided on the side wall by a chemical vapor deposition (CVD) method.

5. The semiconductor device as claimed in claim 1, wherein a height of an interface between the storage electrode and the capacitor extraction electrode is higher than that of a plane on which a lower end of the collar oxide film is an outer edge.

6. The semiconductor device as claimed in claim 1, further comprising:
an isolation region provided on the capacitor extraction electrode;
a drain region provided within the semiconductor substrate including an upper surface of the semiconductor substrate, wherein the drain region is electrically connected to the buried strap region and having the second conductivity type;
a gate insulating film provided on the upper surface of the semiconductor substrate;
a gate electrode provided on the gate insulating film and above the drain region;
a source region provided under the gate insulating film, below the gate electrode, and separate from the drain region within the semiconductor substrate including the upper surface of the semiconductor substrate, wherein the source region having the second conductivity type; and
a bit line electrically connected to the source region.

7. The semiconductor device as claimed in claim 1, wherein in the storage electrode, a width at a side wall in contact with the capacitor insulating film is larger than that at a side wall in contact with the collar oxide film.

8. The semiconductor device as claimed in claim 1, further comprising:
irregularities provided on the bottom face and on the side wall of the semiconductor substrate.

9. A method of making of a trench capacitor comprising:
forming a trench on a surface of a semiconductor substrate having a first conductivity type;
forming a first insulating film on an side wall of the trench;
burying a semiconductor film in the trench on the first insulating film;
etching the first insulating film and the semiconductor film located in an upper part of the trench;
depositing a second insulating film on an exposed side wall of the trench;
etching the semiconductor film;
etching the first insulating film;
forming a plate electrode of a second conductivity type different from the first conductivity type on the exposed side wall of the trench by a vapor-phase diffusion method;
forming a capacitor insulating film on the plate electrode; and
burying a storage electrode in the capacitor insulating film and in the second insulating film within the trench.

10. The method as claimed in claim 9, further comprising:
etching an upper part of the storage electrode and an upper part of the second insulating film;
forming a buried strap region having the second conductivity type in the exposed side wall of the trench; and
burying a capacitor extraction electrode on the storage electrode and on the buried strap region in the trench.

11. The method as claimed in claim 9, wherein the first insulating film is a silicon nitride film, and the second insulating film is a silicon oxide film.

12. The method as claimed in claim 9, wherein the second insulating film is deposited by a CVD method.

13. The method as claimed in claim 9, wherein the semiconductor film is silicon germanium (SiGe).

14. The method as claimed in claim 13, wherein a mole fraction of germanium (Ge) in the silicon germanium film is equal to or greater than 50%.

15. The method as claimed in claim 13, wherein an etchant used in etching the semiconductor film includes hydrogen peroxide(H₂O₂).

16. The method as claimed in claim 9, further comprising:
etching the exposed side wall of the trench after etching the first insulating film and before forming the plate electrode.

17. The method as claimed in claim 9, further comprising:
forming irregularities on the exposed side wall of the trench after etching the first insulating film and before forming the plate electrode.
